(19) United States
(12) Patent Application Publication
(10) Pub. No.: US 2025/0112605 A1
(43) Pub. Date: Apr. 3, 2025

(54) FEEDFORWARD-BASED COMMON-MODE FEEDBACK SCHEME FOR OPAMPS

(71) Applicant: STMicroelectronics International N.V., Geneva (CH)

(72) Inventor: Luv PANDEY, Aligarh (IN)

(21) Appl. No.: 18/884,508

(22) Filed: Sep. 13, 2024

Related U.S. Application Data
(60) Provisional application No. 63/586,211, filed on Sep. 28, 2023.

(51) Int. Cl. H03F 3/45

(52) U.S. Cl. CPC H03F 3/45636; H03F 3/45179

(57) ABSTRACT

In accordance with various embodiments of the present disclosure, an amplifier is provided. In some embodiments, the amplifier comprises a first amplifier stage, a second amplifier stage, a common mode sense amplifier stage, a first common mode feedback (CMFB) loop involving the first amplifier stage, the second amplifier stage, and the common mode sense amplifier stage, and a second CMFB loop involving only the first amplifier stage.

### CROSS-REFERENCE TO RELATED APPLICATIONS

This application claims priority to and the benefit of U.S. Provisional Patent Application Ser. No. 63/586,211, filed on Sep. 28, 2023, and titled “FEEDFORWARD-BASED COMMON-MODE FEEDBACK SCHEME FOR OPAMPS,” the contents of which is incorporated herein by reference in its entirety.

### FIELD OF THE INVENTION

Example embodiments of the present disclosure relate generally to operational amplifiers and, more particularly, to integrated circuits, methods, systems, and apparatuses for providing common-mode feedback in operational amplifiers.

### BACKGROUND

Multiplying digital-to-analog converters (MDACs) used in pipelined-SAR (successive approximation) analog-to-digital converters (ADCs) often use a differential operational amplifier (op-amp) as its core to implement gain. Generally, 2-stage miller compensated op-amps are used due to the requirements of low noise, high gain, and wide output swing.

However, common-mode feedback (CMFB) stability for such an op-amp is not a trivial problem. This is because the common-mode and differential signal paths share almost the same poles and zeroes with one critical difference: their unity gain bandwidths (UGBs) are different.

Along with the requirement of good phase margin (PM), CMFB in a pipelined-SAR ADC needs to have a high common-mode UGB. This is because the MDAC operates in two phases: sampling and amplification. During the sampling phase, the amplifier stages in the op-amp can be turned off in order to conserve power. But this requires an op-amp with fast CMFB so that the op-amp reaches its desired bias-point quickly within the amplification phase when the amplification phase is turned on.

Applicant has identified many technical challenges and difficulties associated with providing CMFB in op-amps. Through applied effort, ingenuity, and innovation, Applicant has solved problems related to providing CMFB in op-amps by developing solutions embodied in the present disclosure, which are described in detail below.

### BRIEF SUMMARY

Various embodiments described herein related to operational amplifiers, integrated circuits, methods, apparatuses, and systems for providing CMFB in op-amps.

In accordance with various embodiments of the present disclosure, an amplifier is provided. In some embodiments, the amplifier comprises a first amplifier stage, a second amplifier stage, a common mode sense amplifier stage, a first common mode feedback (CMFB) loop involving the first amplifier stage, the second amplifier stage, and the common mode sense amplifier stage, and a second CMFB loop involving only the first amplifier stage.

In some embodiments, the first amplifier stage comprises a tail transistor circuit comprising a first tail transistor and a second tail transistor.

In some embodiments, the first CMFB loop determines an average of a first output and a second output of the second amplifier stage and compares the average of the first output and the second output of the second amplifier stage to a fixed reference voltage to control a gate of the first tail transistor.

In some embodiments, the amplifier further comprises a first switched capacitor circuit for determining the average of the first output and the second output of the second amplifier stage.

In some embodiments, the second CMFB loop determines an average of a first output and a second output of the first amplifier stage to control a gate of the second tail transistor.

In some embodiments, the amplifier further comprises a second switched capacitor circuit for determining the average of the first output and the second output of the first amplifier stage.

In accordance with various embodiments of the present disclosure, an integrated circuit is provided. In some embodiments, the integrated circuit comprises an amplifier circuit comprising a first amplifier stage, a second amplifier stage, a common mode sense amplifier stage, a first common mode feedback (CMFB) loop involving the first amplifier stage, the second amplifier stage, and the common mode sense amplifier stage, and a second CMFB loop involving only the first amplifier stage.

In accordance with various embodiments of the present disclosure, a method for providing common mode feedback in an amplifier comprising a first amplifier stage comprising a tail transistor circuit, a second amplifier stage, and a common mode sense amplifier stage is provided. In some embodiments, the method comprises providing a first common mode feedback (CMFB) loop involving the first amplifier stage, the second amplifier stage, and the common mode sense amplifier stage by determining an average of a first output and a second output of the second amplifier stage and comparing the average of the first output and the second output of the second amplifier stage to a fixed reference voltage to control a gate of a first tail transistor of the tail transistor circuit; and providing a second CMFB loop involving only the first amplifier stage by determining an average of a first output and a second output of the first amplifier stage to control a gate of a second tail transistor of the tail transistor circuit.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 illustrates an example circuit design of an example op-amp having first and second CMFB loops, in accordance with some embodiments of the present disclosure;

FIGS. 2 and 3 illustrate a macro model of the example circuit design of FIG. 1; and

FIG. 4 is an example flow diagram illustrating an example method for providing CMFB in op-amps, in accordance with an example embodiment of the present disclosure.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Various embodiments of the present disclosure overcome the above technical challenges and difficulties and provide various technical improvements and advantages based on, for example, but not limited to, providing example integrated circuits, methods, devices, and systems for providing a feedforward-based common-mode feedback scheme for op-amps. In various embodiments, this methodology is helpful in op-amps requiring fast turn-on, such as those used in MDACs used in pipelined-SAR ADCs.

Various embodiments of the present disclosure provide two switched-capacitor CMFB loops running in parallel. In various embodiments, a first CMFB loop (the bigger loop) implements CMFB for the first and second stages of the op-amp and a second CMFB loop (the smaller loop) implements CMFB for only the first stage. In various embodiments, the bigger loop has higher gain but is slower, whereas the smaller loop has lower gain but higher bandwidth. The presence of such two paths in parallel gives rise to zeroes, thereby implementing feedforward compensation for CMFB. This helps in having good CMFB PM with high UGB, which is favorable for amplifiers requiring fast turn-on.

In various embodiments, the first CMFB loop determines an average of a first output and a second output of the second amplifier stage and compares the average of the first output and the second output of the second amplifier stage to a fixed reference voltage to control a gate of a first tail transistor. In various embodiments, a first switched capacitor circuit is used for determining the average of the first output and the second output of the second amplifier stage.

In various embodiments, the second CMFB loop determines an average of a first output and a second output of the first amplifier stage to control a gate of the second tail transistor. In various embodiments, a second switched capacitor circuit is used for determining the average of the first output and the second output of the first amplifier stage.

The feedforward-based common-mode feedback scheme of various embodiments of the present disclosure may be used with any suitable op-amps, such as but not limited to 2-stage miller compensated op-amps and 2-stage inverter op-amps.

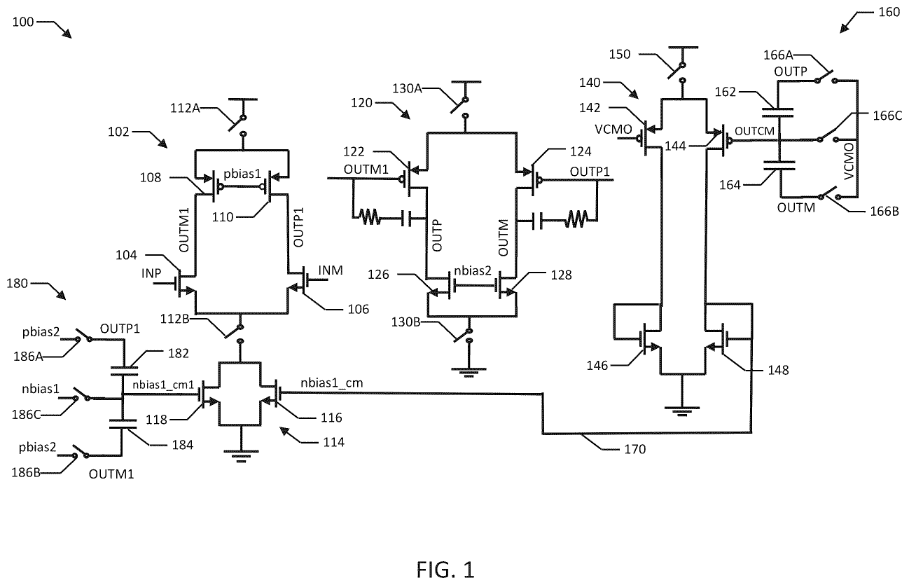

FIG. 1 illustrates an example circuit design of an op-amp having two CMFB loops as described herein. The circuit design of FIG. 1 is separated and spread out for clarity. The circuit design of FIG. 1 illustrates an op-amp 100 that includes a first amplifier stage 102 and a second amplifier stage 120. In the illustrated embodiment, the first amplifier stage 102 comprises a first NMOS transistors 104 receiving input INP, a second NMOS transistor 106 receiving input INM, first and second PMOS load transistors 108, 110 with a signal pbias1 between their gates, and switches 112A, 112B that close when the op-amp 100 is in use and open when the op-amp 100 is not in use. In the illustrated embodiment, the output OUTM1 of the first amplifier stage 102 is between the first NMOS transistor 104 and the first PMOS load transistor 108, while the output OUTP1 of the first amplifier stage 102 is between the second NMOS transistor 106 and the second PMOS load transistor 110. In the illustrated embodiment, the first amplifier stage 102 comprises a tail transistor 114 comprising a first NMOS transistor 116 and a second NMOS transistor 118.

In the illustrated embodiment, the second amplifier stage 120 comprises a first PMOS transistors 122 receiving output OUTM1 from the first amplifier stage 102, a second PMOS transistor 124 receiving output OUTP1 from the first amplifier stage 102, first and second NMOS load transistors 126, 128 with a signal nbias2 between their gates, and switches 130A, 130B that close when the op-amp 100 is in use and open when the op-amp 100 is not in use. In the illustrated embodiment, the output OUTP of the second amplifier stage 120 is between the first PMOS transistor 122 and the first NMOS load transistor 126, while the output OUTM of the second amplifier stage 120 is between the second PMOS load transistor 124 and the second NMOS transistor 128.

In the illustrated embodiment, the op-amp 100 includes a first switched capacitor circuit 160 that comprises first and second capacitors 162, 164. In the illustrated embodiment, a first leg of the first capacitor 162 is connected to the output OUTP of the second amplifier stage 120, a first leg of the second capacitor 164 is connected to the output OUTM of the second amplifier stage 120, the second legs of the first and second capacitors 162, 164 are connected and form the output OUTCM of the first switched capacitor circuit 160. In the illustrated embodiment, three switches 166A, 166B, 166C connect, respectively, the first leg of the first capacitor 162, the first leg of the second capacitor 164, and the second legs of the first and second capacitors 162, 164 to a reference voltage VCMO. In the illustrated embodiment, the three switches 166A, 166B, 166C open when the op-amp 100 is in use and close when the op-amp 100 is not in usc.

In the illustrated embodiment, the op-amp 100 includes a common mode sense amplifier 140 that comprises first and second PMOS transistors 142, 144, first and second NMOS transistors 146, 148, and a switch 150 that closes when the op-amp 100 is in use and opens when the op-amp 100 is not in use. In the illustrated embodiment, the reference voltage VCMO is connected to the gate of the first PMOS transistor 142, the output OUTCM of the first switched capacitor circuit 160 is connected to the gate of the second PMOS transistor 144, and the gates of the first and second NMOS transistors 146, 148 are connected to the gate of the first NMOS transistor 116 of the tail transistor 114 via line 170.

In the illustrated embodiment, the op-amp 100 includes a second switched capacitor circuit 180 that comprises first and second capacitors 182, 184. In the illustrated embodiment, a first leg of the first capacitor 182 is connected to the output OUTP1 of the first amplifier stage 102, a first leg of the second capacitor 184 is connected to the output OUTM1 of the first amplifier stage 102, the second legs of the first and second capacitors 182, 184 are connected and form the output nbias1_cm1 of the second switched capacitor circuit 180. In the illustrated embodiment, three switches 186A, 186B, 186C connect, respectively, the first leg of the first capacitor 182 to an input pbias2, the first leg of the second capacitor 184 to an input pbias2, and the second legs of the first and second capacitors 182, 184 to an input nbias1. In some embodiments, the input pbias2 is the gate-voltage of a diode-connected transistor whose size and bias-current are scaled versions of the sizes and currents through the first and second PMOS transistors 122, 124 of the second amplifier stage 120, ensuring that the gate-to-source voltage of the diode-connected transistor matches with the gate-to-source voltages of the first and second PMOS transistors 122, 124. In some embodiments, the input nbias1 is the gate-voltage of a diode-connected transistor whose size and bias-current are scaled versions of the sizes and currents through the first and second NMOS transistors 116, 118 of the tail transistor 114, ensuring that the gate-to-source voltage of the diode-connected transistor matches with the gate-to-source voltages of the first and second NMOS transistors 116, 118 of the tail transistor 114. In the illustrated embodiment, the three switches 186A, 186B, 186C open when the op-amp 100 is in use and close when the op-amp 100 is not in use.

In various embodiments, the first switched capacitor circuit 160 and the common mode sense amplifier 140 form the first CMFB loop. In various embodiments, the first CMFB loop determines an average of output OUTP and output OUTM of the second amplifier stage 120 and compares this average to VCMO to control the gate of the first tail transistor 116 (this signal is labeled nbias1_cm in FIG. 1). In various alternative embodiments, other suitable mechanisms may be used to determines an average of the outputs of the second amplifier stage, including but not limited to a resistive sensing circuit.

In various embodiments, the second switched capacitor circuit 180 forms the second CMFB loop. In various embodiments, the second CMFB loop determines an average of output OUTP1 and output OUTM1 of the first amplifier stage 102 to control the gate of the second tail transistor 118 (this signal is labeled nbias1_cm1 in FIG. 1). In various alternative embodiments, other suitable mechanisms may be used to determines an average of the outputs of the first amplifier stage, including but not limited to a resistive sensing circuit.

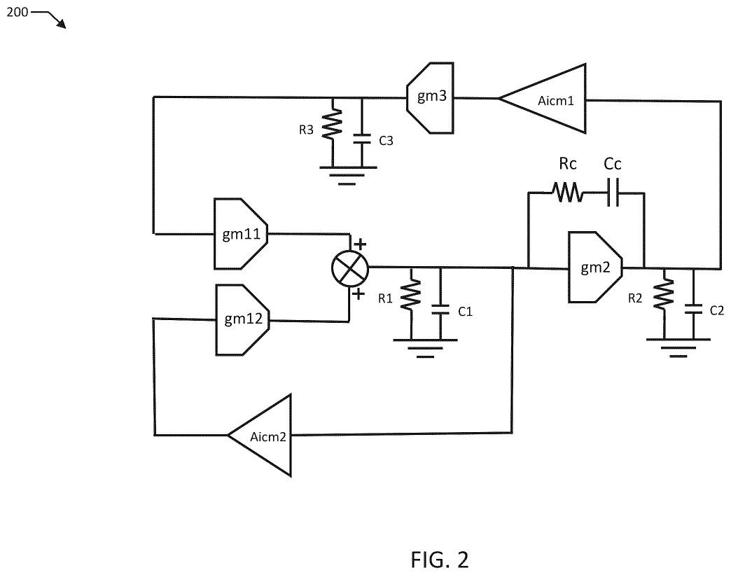

Referring now to FIG. 2, a macro model 200 of the example circuit design of FIG. 1 is illustrated. In FIG. 2, gm2 represents the transconductance of the first and second PMOS transistors 122, 124 of the second amplifier stage 120, capacitor Cc and resistor Rc represent the miller-capacitor and the associated nulling resistor required for frequency compensation of the OPAMP 100, resistor R2 represents the output resistance of the second amplifier stage 120, capacitor C2 represents any parasitic capacitance of the second amplifier stage 120, Aicm1 represents the common mode gain of the first switched capacitor circuit 160 (the common mode gain may be assumed to be 1 if there is no parasitic capacitance, but is likely to be less than 1 in a real world application), gm3 represents the transconductance of the first and second PMOS transistors 142, 144 of the common mode sense amplifier140, resistor R3 represents the output resistance of the common mode sense amplifier 140, capacitor C3 represents any parasitic capacitance of the common mode sense amplifier 140, gm11 represents the transconductance of the first NMOS transistor 116 of the tail transistor 114, gm12 represents the transconductance of the second NMOS transistor 118 of the tail transistor 114, Aicm2 represents the common mode gain of the second switched capacitor circuit 180 (the common mode gain may be assumed to be 1 if there is no parasitic capacitance, but is likely to be less than 1 in a real world application), resistor R1 represents the output resistance of the first amplifier stage 102, and capacitor C1 represents any parasitic capacitance of the first amplifier stage 102.

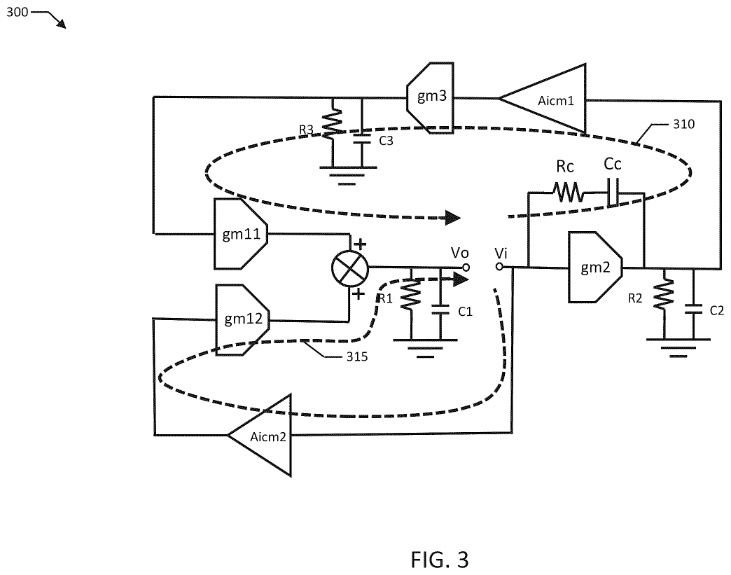

Referring now to FIG. 3, a macro model 300 of the example circuit design of FIG. 1 is illustrated. The macro model 300 of FIG. 3 is identical to the macro model 200 of FIG. 2, except that a break point from Vi to Vo has been created. Generally, a stability analysis is performed by applying a stimulus at Vi and observing the output at Vo. When performing a stability analysis with multiple loops, a break point common to all loops is chosen. FIG. 3 illustrates a first CMFB loop 310 and a second CMFB loop 315.

As seen in FIG. 3, the first CMFB loop 310 involves three amplifier stages (first stage, second stage, and sense amplifier). The first CMFB loop 310 is larger, has a higher gain, has more nodes and more poles, and is slower than the second CMFB loop 315. The second CMFB loop 315 involves only a single amplifier (first stage). The second CMFB loop 315 is smaller, has lower gain, and is faster than the first CMFB loop 310.

The presence of one slower and one faster path running in parallel improves stability of the overall loop due to the presence of zeroes. The location of zeroes can be found by equating the currents through trans-conductors gm11 and gm12 using the following formula:

$$\frac{( - gm 2 * R 2 ) ( 1 + sCc ( Rc - \frac{1}{gm 2} )}{( 1 + s * \frac{{R}_{2} * ( Cc * {C}_{1} + Cc * C 2 + {C}_{1} * {C}_{2} )}{{C}_{1} + ( 1 + gm 2 * {R}_{2} ) * {C}_{c}} ) ( 1 + s * Rc * C 1 )} * \frac{Aicm 1 * ( - gm 3 * R 3 )}{( 1 + s * R 3 * C 3 )} * ( - gm 11 ) = ( - gm 12 ) * Aicm 2 ,$$

where s represents frequency for finding the location of zero and the other terms are as defined above.

Various embodiments of the present disclosure provide common-mode feedback in operational amplifiers with acceptable levels of DC gain, unity gain bandwidth, and phase margin as compared to uncompensated operational amplifiers and other approaches to compensation that have been used.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), memory(ies), circuitry(ies), and/or the like to perform their associated functions such that duplicate hardware is not required for each set of circuitry.

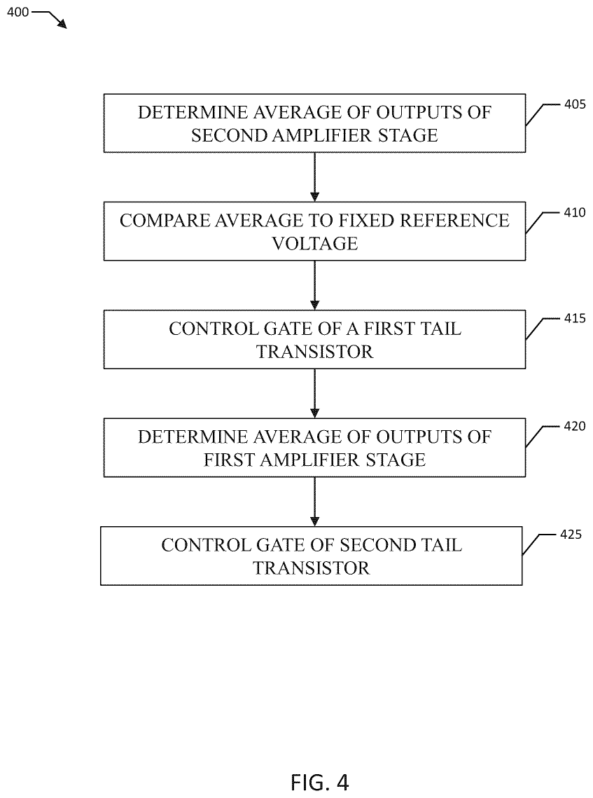

Reference will now be made to FIG. 4, which provides a flowchart illustrating example steps, processes, procedures, and/or operations in accordance with various embodiments of the present disclosure. Various methods described herein, including, for example, example methods as shown in FIG. 4, may provide various technical benefits and improvements. It is noted that each block of the flowchart, and combinations of blocks in the flowchart, may be implemented by various means such as hardware, firmware, circuitry and/or other devices associated with execution of software including one or more computer program instructions. For example, one or more of the procedures described in FIG. 4 may be embodied by computer program instructions, which may be stored by a non-transitory memory of an apparatus employing an embodiment of the present disclosure and executed by a processor in the apparatus. These computer program instructions may direct a computer or other programmable apparatus to function in a particular manner, such that the instructions stored in the computer-readable storage memory produce an article of manufacture, the execution of which implements the function specified in the flowchart block(s).

As described above and as will be appreciated based on this disclosure, embodiments of the present disclosure may be configured as methods, mobile devices, backend network devices, and the like. Accordingly, embodiments may comprise various means including entirely of hardware or any combination of software and hardware. Furthermore, embodiments may take the form of a computer program product on at least one non-transitory computer-readable storage medium having computer-readable program instructions (e.g., computer software) embodied in the storage medium. Similarly, embodiments may take the form of a computer program code stored on at least one non-transitory computer-readable storage medium. Any suitable computer-readable storage medium may be utilized including non-transitory hard disks, CD-ROMs, flash memory, optical storage devices, or magnetic storage devices.

Having described example systems, apparatuses, computing environments, and user interfaces associated with embodiments of the present disclosure, example flowcharts including various operations performed by the apparatuses and/or systems described herein will now be discussed. It should be appreciated that each of the flowcharts depicts an example process that may be performed by one or more of the apparatuses, systems, and/or devices described herein, for example utilizing one or more of the components thereof. The blocks indicating operations of each process may be arranged in any of a number of ways, as depicted and described herein. In some such embodiments, one or more blocks of any of the processes described herein occur concurrently rather than sequentially. In some such embodiments, one or more blocks of any of the processes described herein occur in-between one or more blocks of another process, before one or more blocks of another process, and/or otherwise operates as a sub-process of a second process. Additionally or alternative, any of the processes may include some or all of the steps described and/or depicted, including one or more optional operational blocks in some embodiments. In regards to the below flowcharts, one or more of the depicted blocks may be optional in some, or all, embodiments of the disclosure. Optional blocks are depicted with broken (or “dashed”) lines. Similarly, it should be appreciated that one or more of the operations of each flowchart may be combinable, replaceable, re-ordered, and/or otherwise altered as described herein.

Referring now to FIG. 4, an example flow diagram illustrating an example method 400 for providing CMFB in op-amps in accordance with some embodiments of the present disclosure is illustrated. In some embodiments, the example method 400 may be implemented by an example apparatus described herein, including, but not limited to, the example op-amp 100 described above in connection with FIG. 1.

In the example method shown in FIG. 4, the example method 400 starts at step/operation 405. At step/operation 405, an op-amp (such as, but not limited to, the op-amp 100 described above in connection with FIG. 1) determines an average of the outputs of a second amplifier stage of the op-amp.

At step/operation 410, one or more components within an op-amp (such as, but not limited to, the op-amp 100 described above in connection with FIG. 1) compares the average of the outputs of the second amplifier stage of the op-amp to a fixed reference voltage.

At step/operation 415, one or more components within an op-amp (such as, but not limited to, the op-amp 100 described above in connection with FIG. 1) controls a gate of a first tail transistor of the tail transistor circuit of the op-amp with the value determined at step/operation 410 and step/operation 415.

At step/operation 420, one or more components within an op-amp (such as, but not limited to, the op-amp 100 described above in connection with FIG. 1) determines an average of the outputs of a first amplifier stage of the op-amp.

At step/operation 425, one or more components within an op-amp (such as, but not limited to, the op-amp 100 described above in connection with FIG. 1) controls a gate of a second tail transistor of the tail transistor circuit of the op-amp with the value determined at step/operation 420.

In some embodiments, the example method shown in FIG. 4 continuously repeats.

### CONCLUSION

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to fragmented wideband tympanometry techniques for true wireless stereo, however, one skilled in the art may recognize that such principles may be applied to any audio device. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of integrated circuit which has one or more operational amplifiers, such as but not limited to general purpose micro-controllers, RADAR systems, RF systems, etc.

Within the appended claims, unless the specific term “means for” or “step for” is used within a given claim, it is not intended that the claim be interpreted under 35 U.S.C. 112, paragraph 6.

What is claimed is:

1. An amplifier comprising:
a first amplifier stage;
a second amplifier stage;
a common mode sense amplifier stage;
a first common mode feedback (CMFB) loop involving the first amplifier stage, the second amplifier stage, and the common mode sense amplifier stage; and
a second CMFB loop involving only the first amplifier stage.

2. The amplifier of claim 1, wherein the first amplifier stage comprises a tail transistor circuit comprising a first tail transistor and a second tail transistor.

3. The amplifier of claim 2, wherein the first CMFB loop determines an average of a first output and a second output of the second amplifier stage and compares the average of the first output and the second output of the second amplifier stage to a fixed reference voltage to control a gate of the first tail transistor.

4. The amplifier of claim 3, further comprising a first switched capacitor circuit for determining the average of the first output and the second output of the second amplifier stage.

5. The amplifier of claim 3, wherein the second CMFB loop determines an average of a first output and a second output of the first amplifier stage to control a gate of the second tail transistor.

6. The amplifier of claim 5, further comprising a second switched capacitor circuit for determining the average of the first output and the second output of the first amplifier stage.

7. An integrated circuit comprising:
an amplifier circuit comprising:
a first amplifier stage;
a second amplifier stage;
a common mode sense amplifier stage;
a first common mode feedback (CMFB) loop involving the first amplifier stage, the second amplifier stage, and the common mode sense amplifier stage; and
a second CMFB loop involving only the first amplifier stage.

8. The integrated circuit of claim 7, wherein the first amplifier stage comprises a tail transistor circuit comprising a first tail transistor and a second tail transistor.

9. The integrated circuit of claim 8, wherein the first CMFB loop determines an average of a first output and a second output of the second amplifier stage and compares the average of the first output and the second output of the second amplifier stage to a fixed reference voltage to control a gate of the first tail transistor.

10. The integrated circuit of claim 9, further comprising a first switched capacitor circuit for determining the average of the first output and the second output of the second amplifier stage.

11. The integrated circuit of claim 9, wherein the second CMFB loop determines an average of a first output and a second output of the first amplifier stage to control a gate of the second tail transistor.

12. The integrated circuit of claim 11, further comprising a second switched capacitor circuit for determining the average of the first output and the second output of the first amplifier stage.

13. A method for providing common mode feedback in an amplifier comprising a first amplifier stage comprising a tail transistor circuit, a second amplifier stage, and a common mode sense amplifier stage, the method comprising:
providing a first common mode feedback (CMFB) loop involving the first amplifier stage, the second amplifier stage, and the common mode sense amplifier stage by determining an average of a first output and a second output of the second amplifier stage and comparing the average of the first output and the second output of the second amplifier stage to a fixed reference voltage to control a gate of a first tail transistor of the tail transistor circuit; and
providing a second CMFB loop involving only the first amplifier stage by determining an average of a first output and a second output of the first amplifier stage to control a gate of a second tail transistor of the tail transistor circuit.

14. The method of claim 13, wherein a first switched capacitor circuit determines the average of the first output and the second output of the second amplifier stage.

15. The method of claim 14, wherein a second switched capacitor circuit determines the average of the first output and the second output of the first amplifier stage.
